(19) United States
(12) Patent Application Publication
(10) Pub. No.: US 2026/0284944 A1
(43) Pub. Date: Sep. 24, 2026

(54) METHOD FOR MANUFACTURING SOLAR CELL MODULE

(71) Applicants: Hyundai Motor Company, Seoul (KR); Kia Corporation, Seoul (KR); SOLARSTIC CO., LTD., Gunpo-si (KR)

(72) Inventors: Hyun Jun KIM, Hwaseong-si (KR); Seongeun JANG, Hwaseong-Si (KR); Sung Geun PARK, Hwaseong-si (KR)

(73) Assignees: Hyundai Motor Company, Seoul (KR); Kia Corporation, Seoul (KR); SOLARSTIC CO., LTD., Gunpo-si (KR)

(21) Appl. No.: 19/337,256

(22) Filed: Sep. 23, 2025

(30) Foreign Application Priority Data
Mar. 18, 2025 (KR) 10-2025-0034520

(51) Int. Cl. B29C 45/14; B29C 45/56; B29L 31/34

(52) U.S. Cl. CPC B29C 45/14434; B29C 45/561; B29L 2031/34

(57) ABSTRACT

A method for manufacturing a solar cell module includes manufacturing a preform solar cell by connecting a plurality of solar cells, inserting and mounting the preform solar cell into an injection mold, closing the injection mold and injecting and filling a polymer resin into the injection mold to cover the preform solar cell, operating the injection mold to apply a compressive force to the polymer resin filled in the injection mold, curing the polymer resin, and opening the injection mold to extract a solar cell injection molded product.

### CROSS-REFERENCE TO RELATED APPLICATION

The present application claims priority to and the benefit of Korean Patent Application No. 10-2025-0034520 filed at the Korean Intellectual Property Office on Mar. 18, 2025, the entire contents of which are incorporated herein by reference.

### BACKGROUND OF THE PRESENT DISCLOSURE

### Field of the Present Disclosure

The present disclosure relates to a method for manufacturing a solar cell module, and more specifically, to a method for manufacturing a solar cell module using an injection compression molding method.

### Description of Related Art

In general, a solar cell module 8 is manufactured by inserting a solar cell 1 into the internal surface of a tempered glass 2, as shown in FIG. 1, and using a sealant 3, which is an adhesive film, to compress the interface of the solar cell 1 in a high-temperature and vacuum environment to produce a panel. Accordingly, a frame-shaped aluminum frame 5 is attached to the edge of the tempered glass 2, which is the front surface of the panel, a back sheet 4 is attached to the back surface of the panel, and a junction box 6 is connected to manufacture the solar cell module 8.

Solar cell modules manufactured in the instant way have limited design freedom as they cannot go beyond a flat shape, and they have the disadvantage of increasing weight as tempered glass and aluminum frames account for approximately 90% of the weight of the solar cell module.

### BRIEF SUMMARY

Accordingly, the present disclosure is directed to solve the above-described problems, and attempts to provide a method for manufacturing a solar cell module, which is lightweight, transparent, and improves design freedom by manufacturing a solar cell module by applying an injection compression molding process used in manufacturing a plastic molded product.

In various aspects of the present disclosure, a method for manufacturing a solar cell module according to an exemplary embodiment of the present disclosure includes manufacturing a preform solar cell by connecting a plurality of solar cells, inserting and mounting the preform solar cell into an injection mold, closing the injection mold and injecting and filling a polymer resin into the injection mold to cover the preform solar cell, operating the injection mold to apply a compressive force to the polymer resin filled in the injection mold, curing the polymer resin, and opening the injection mold to extract a solar cell injection molded product.

In various aspects of the present disclosure, in the manufacturing of the preform solar cell, the preform solar cell may be formed by preparing a plurality of solar cells connected to a conductive string between electrodes, adhering a film-like transparent polymer sheet to the front surface of the plurality of solar cells by an adhesive sheet, and adhering a film-like back sheet to the back surface of the plurality of solar cell cells.

In various aspects of the present disclosure, the transparent polymer sheet may be a made of polycarbonate (PC).

In various aspects of the present disclosure, the adhesive sheet may be made of any one of ethylene vinyl acetate (EVA), polyolefin elastomer (POE), and an acrylic transparent sheet.

In various aspects of the present disclosure, the adhesive sheet may have a thickness of 0.5 mm or more and 0.7 mm or less.

In various aspects of the present disclosure, in the inserting and mounting of the preform solar cell into the injection mold, the injection mold may include a fixed mold on which the preform solar cell is disposed and a moving mold that moves relative to the fixed mold.

In various aspects of the present disclosure, the fixed mold may include a runner formed there inside, which is a path through which the polymer resin passes, and a sprue formed on an outer portion of the fixed mold, wherein the spruce is connected to a first end portion of the runner and is an inlet through which the polymer resin flows in from an external injection molding nozzle.

In various aspects of the present disclosure, the polymer resin may be supplied into the runner through the sprue, and the polymer resin is discharged through a gate formed on the inside of the fixed mold and connected to a second end portion of the runner to cover the preform solar cell disposed on the fixed mold.

In various aspects of the present disclosure, the gate may be disposed on both sides of a space where the preform solar cell is disposed, and may be formed at a position spaced apart from the edge portion of the fixed mold toward the center of the fixed mold.

In various aspects of the present disclosure, a step may be formed between the preform solar cell and the fixed mold, and the polymer resin may be filled in an upper space of the preform solar cell formed by the step.

In various aspects of the present disclosure, the polymer resin may cover the surface of the preform solar cell and may then be induced to fill the edge portion where the step is formed.

In various aspects of the present disclosure, in the injecting and filling of the polymer resin into the injection mold, the fixed mold and the moving mold may be closed to form a gap.

In various aspects of the present disclosure, the gap may be formed to be 2 to 2.5 times greater than the thickness of the preform solar cell.

In various aspects of the present disclosure, the polymer resin may be filled only in some space within the gap.

In various aspects of the present disclosure, the applying of the compressive force to the polymer resin filled in the injection mold may be performed before the polymer resin is completely cured within the injection mold.

In various aspects of the present disclosure, in the curing of the polymer resin, the cured polymer resin may be formed on the upper portion of the preform solar cell to a thickness of 2.5 mm or more and 5 mm or less, and the preform solar cell may have a thickness of 2.1 mm or more and 2.5 mm or less.

In various aspects of the present disclosure, by manufacturing a solar cell module by applying an injection mold used in a plastic molding process, it is possible to produce a solar cell module product with a variety of elegant designs, departing from the conventional simple panel structure made of tempered glass and an aluminum frame.

Additionally, by eliminating the tempered glass and aluminum frame and applying polymer resin, it is possible to reduce the weight drastically and produce a transparent product.

Furthermore, since it is possible to produce packaged solar cell modules in a single plastic injection molding process using an injection mold, production efficiency may be maximized.

Furthermore, by applying the injection compression molding process, which simultaneously applies injection molding and mold compression, to the manufacturing of solar cell modules, the solar cells inside the mold are not damaged, reducing product defects and enabling the production of reliable products.

### BRIEF DESCRIPTION OF THE DRAWINGS

FIG. 1 illustrates a solar cell module manufactured by a conventional method.

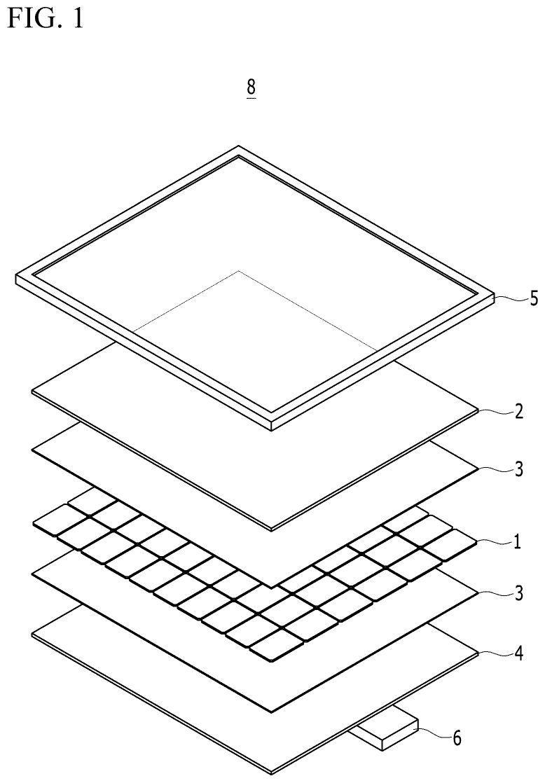

FIG. 2 is a flowchart showing a method for manufacturing a solar cell module according to an exemplary embodiment of the present disclosure.

FIG. 3 illustrates a preform solar cell manufactured in the method for manufacturing the solar cell module according to an exemplary embodiment of the present disclosure.

FIG. 4 illustrates an injection mold used in the method for manufacturing the solar cell module according to an exemplary embodiment of the present disclosure.

FIG. 5 illustrates a state in which a preform solar cell is disposed in the injection mold in the method for manufacturing the solar cell module according to an exemplary embodiment of the present disclosure.

FIG. 6 illustrates a state in which a polymer resin is injected into the injection mold in the method for manufacturing the solar cell module according to an exemplary embodiment of the present disclosure.

FIG. 7 illustrates a state in which the polymer resin is filled into the injection mold in the method for manufacturing the solar cell module according to an exemplary embodiment of the present disclosure.

FIG. 8 illustrates a state in which a compressive force is applied to the polymer resin filled in the injection mold in the method for manufacturing the solar cell module according to an exemplary embodiment of the present disclosure.

FIG. 9 illustrates a solar cell injection molded product manufactured by the method for manufacturing the solar cell module according to an exemplary embodiment of the present disclosure.

### DETAILED DESCRIPTION

Hereinafter, the present disclosure will be described in detail with reference to the accompanying drawings, in which embodiments of the present disclosure are shown. As those skilled in the art would realize, the described embodiments may be modified in various different ways, all without departing from the spirit or scope of the present disclosure.

In addition, in various exemplary embodiments of the present disclosure, components having the same configuration are representatively described in an exemplary embodiment using the same reference numerals, and in other exemplary embodiments of the present disclosure, only configurations different from those of the representative embodiment are described.

It should be noted that the drawings are schematic and not drawn to scale. The relative dimensions and proportions of parts in the drawings are exaggerated or reduced in size for clarity and convenience, and any dimensions are for illustrative purposes only and are not limited. Where identical structures, elements, or parts appear in two or more drawings, like reference numerals are used to indicate like features. When it is stated that a part is “on” or “above” another part, it can be directly on the other part, or other parts may be disposed therebetween.

The exemplary embodiment of the present disclosure specifically illustrates an exemplary embodiment of the present disclosure. As a result, many variations of the present disclosure are expected. Therefore, the exemplary embodiments are not limited to a particular shape of the illustrated region, but also include modifications of the shape—for example, variations of the shape by manufacturing.

Hereinafter, a method for manufacturing a solar cell module according to an exemplary embodiment of the present disclosure will be described in detail with reference to the appended drawings.

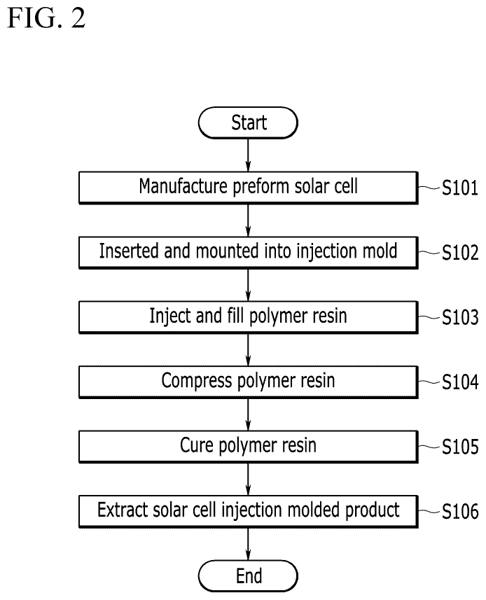

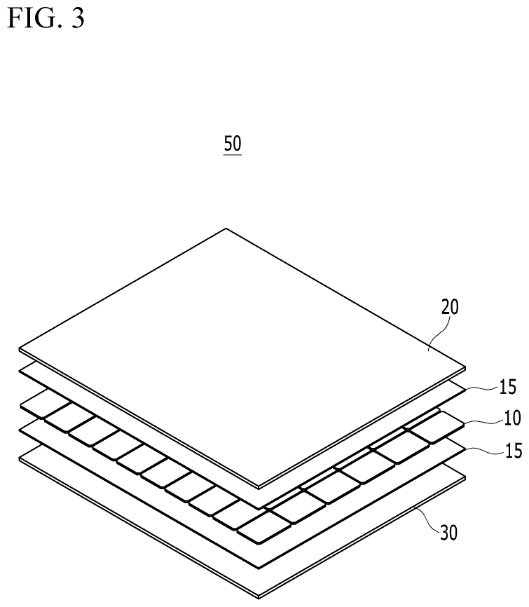

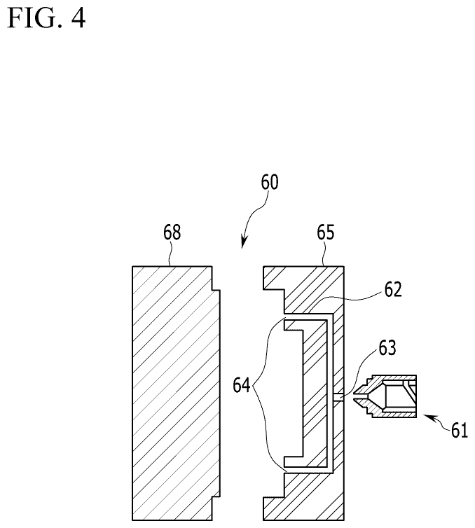

FIG. 2 is a flowchart showing a method for manufacturing a solar cell module according to an exemplary embodiment of the present disclosure, FIG. 3 illustrates a preform solar cell manufactured in the method for manufacturing the solar cell module according to an exemplary embodiment of the present disclosure, and FIG. 4 illustrates an injection mold used in the method for manufacturing the solar cell module according to an exemplary embodiment of the present disclosure.

Referring to FIG. 2, the method for manufacturing the solar cell module according to an exemplary embodiment of the present disclosure first connects a plurality of solar cells 10 to manufacture a preform solar cell 50 (S101).

As shown in FIG. 3, the preform solar cell 50 includes a structure in which the plurality of solar cells 10 are provided and disposed, and the electrodes of the solar cells 10 are connected to a conductive string. The plurality of solar cells 10 are disposed to extend in horizontal and vertical directions and are connected in series to each other by a string between electrodes including the same polarity.

A film-like transparent polymer sheet 20 with a certain thickness or greater is adhered to the front surface of the plurality of solar cells 10 to protect the solar cells 10. The transparent polymer sheet 20 may be attached to the front surface of the solar cells 10 by an adhesive sheet 15.

Additionally, a film-like back sheet 30 may be attached to the back surface of the plurality of solar cells 10 by the adhesive sheet 15.

At the present time, the transparent polymer sheet 20 may be made of polycarbonate (PC). Additionally, the adhesive sheet 15 may be made of any one of ethylene vinyl acetate (EVA), polyolefin elastomer (POE), and an acrylic transparent sheet. The adhesive sheet 15 may have a thickness of about 0.5 mm or more and about 0.7 mm or less.

Accordingly, an injection mold 60 is prepared, and the manufactured preform solar cell 50 is inserted and disposed into an injection mold 60 (S102).

As shown in FIG. 4, the injection mold 60 includes a fixed mold 65 and a moving mold 68. A space is disposed in the fixed mold 65 for mounting the preform solar cell 50, and the moving mold 68 is disposed to face the fixed mold 65 and moves relative to the fixed mold 65 to be in close contact with or spaced apart from the fixed mold 65.

The fixed mold 65 may be formed to include an overall concave shape so that the preform solar cell 50 may be disposed on the inside of the fixed mold 65, and the moving mold 68 may include an overall convex shape to match the concave shape of the fixed mold 65.

Inside the fixed mold 65, a runner 62 is formed, which is a path through which a polymer resin P passes, and on the outside of the fixed mold 65, a sprue 63 is formed, which is connected to the runner 62, and on the inside of the fixed mold 65, a gate 64 is formed, which is connected to the runner 62.

The sprue 63 is connected to an injection molding nozzle 61 that is disposed outside of the fixed mold 65 and supplies the polymer resin P, and the polymer resin P that flows into the fixed mold 65 through the sprue 63 flows through the inside of the fixed mold 65 through the runner 62. The polymer resin P flowing through the inside of the runner 62 is filled into the mounting space of the preform solar cell 50 inside the fixed mold 65 through the gate 64 formed inside the fixed mold 65.

The gate 64 may be disposed on both sides of the internal space of the fixed mold 65 where the preform solar cell 50 is disposed—that is, at the edge portion of the internal space—and may be formed at a position spaced apart from the edge portion of the fixed mold 65 toward the center portion of the fixed mold 65.

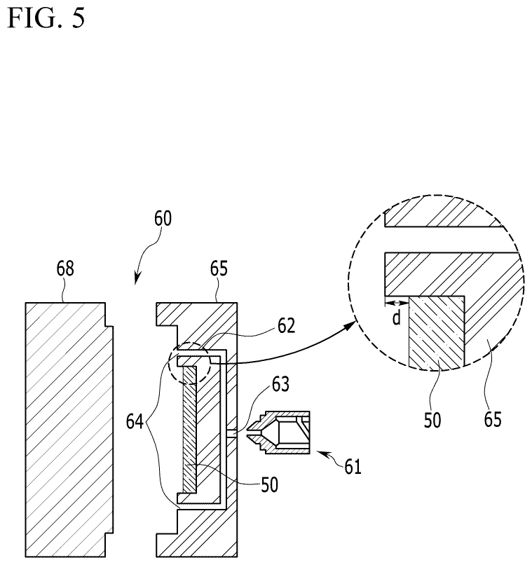

FIG. 5 illustrates a state in which a preform solar cell is disposed in the injection mold 60 in the method for manufacturing the solar cell module according to an exemplary embodiment of the present disclosure.

As shown in FIG. 5, in the internal space of the fixed mold in which the preform solar cell 50 is disposed, a step (d) is formed between the upper surface of the preform solar cell 50 and the upper surface of the fixed mold 65. The internal space of the fixed mold 65 formed by the step (d) becomes a space filled with the polymer resin P.

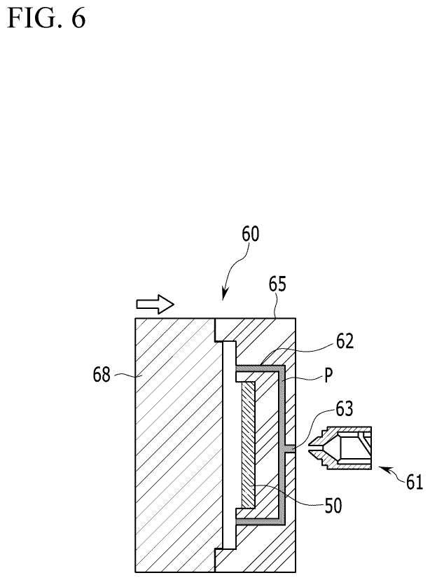

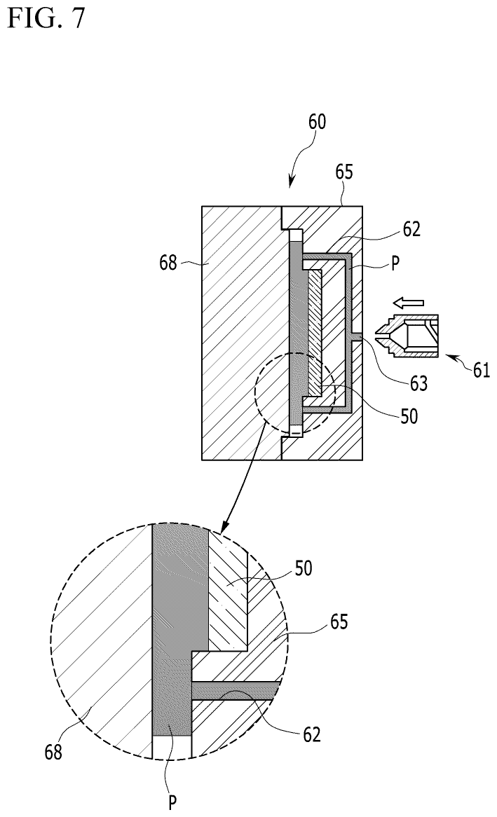

FIG. 6 illustrates a state in which a polymer resin is injected into the injection mold in the method for manufacturing the solar cell module according to an exemplary embodiment of the present disclosure, and FIG. 7 illustrates a state in which the polymer resin is filled into the injection mold in the method for manufacturing the solar cell module according to an exemplary embodiment of the present disclosure.

After the preform solar cell 50 is inserted and disposed into the injection mold 60, as shown in FIG. 6 and FIG. 7, the moving mold 68 is moved toward the fixed mold 65 to close the injection mold 60, and the polymer resin P is injected and filled into the injection mold 60 to cover the upper surface of the preform solar cell 50 (S103).

The polymer resin P injected into the injection mold 60 through the sprue 63 flows through the runner 62 and is supplied to the upper portion of the preform solar cell 50 through the gate 64 disposed at the edge portion of the preform solar cell 50. The polymer resin P is filled into the space formed by the step (d) formed between the preform solar cell 50 and the fixed mold 65. At the instant time, the polymer resin P may be induced to cover the upper surface of the preform solar cell 50 and fill the edge portion where the step (d) is formed.

On the other hand, the fixed mold 65 and the moving mold 68 may be closed to form a gap. That is, when the fixed mold 65 and the moving mold 68 are closed, a space formed by the gap between the fixed mold 65 and the moving mold 68 may be disposed on the upper portion of the space formed by the step (d) formed between the preform solar cell 50 and the fixed mold 65. The present space may be secured with a thickness of about 200% to about 250% of the thickness of the preform solar cell 50.

Additionally, the polymer resin P may be completely filled in the space formed by the step (d) formed between the preform solar cell 50 and the fixed mold 65, and then only partially filled in the space formed by the gap between the fixed mold 65 and the moving mold 68.

By only partially filling the space formed by the gap between the fixed mold 65 and the moving mold 68 with the polymer resin P, a lower level of pressure is formed compared to when it is completely filled, which allows the polymer resin P to be evenly distributed on the surface of the preform solar cell 50, and may dramatically reduce the risk of damage to the preform solar cell 50.

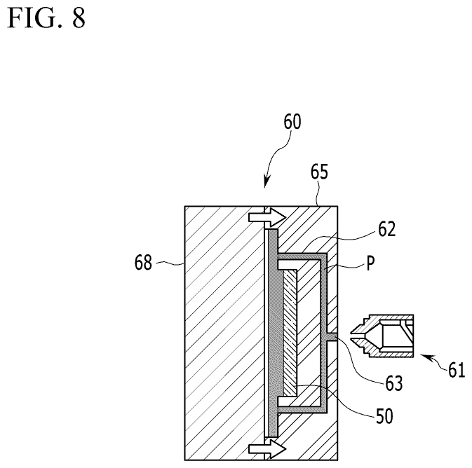

FIG. 8 illustrates a state in which a compressive force is applied to the polymer resin P filled in the injection mold 60 in the method for manufacturing the solar cell module according to an exemplary embodiment of the present disclosure.

After the polymer resin P is injected into the injection mold 60 and filled, as shown in FIG. 8, the injection mold 60 is operated to apply a compressive force to the polymer resin P filled in the injection mold 60 (S104).

When the moving mold 68 moves toward the fixed mold 65 and comes into contact with it, the polymer resin P filled in a portion of the space formed by the gap between the fixed mold 65 and the moving mold 68 is compressed and spread to be completely filled. In the instant state, when the moving mold 68 is further pushed toward the fixed mold 65 and compressed, a compressive force is applied to the polymer resin P, and the shape of a complete molded product is formed. At the instant time, the moving speed of the moving mold 68, the applied pressure, and the timing may be set depending on the shape of the molded product and the type of polymer resin P.

The step (S104) of applying a compressive force to the polymer resin P may be performed before the polymer resin P is completely cured within the injection mold 60.

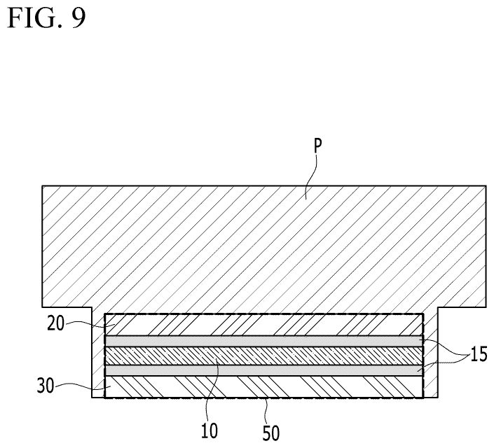

FIG. 9 illustrates a solar cell injection molded product manufactured by the method for manufacturing the solar cell module according to an exemplary embodiment of the present disclosure.

After applying a compressive force to the polymer resin P, the polymer resin P is cured (S105). Curing of the heated and pressurized polymer resin P may proceed while lowering the temperature of the injection mold 60 for a predetermined time period. The curing speed may be set by the type of the polymer resin P, the shape of the molded product, the molding temperature, or the like.

Afterwards, when the curing of the polymer resin P is completed, the injection mold 60 is opened to extract the solar cell injection molded product (S106).

As shown in FIG. 9, the solar cell injection molded product is in the shape of the polymer resin P cured on the front and side surfaces of the preform solar cell 50 as shown in FIG. 3. That is, the solar cell injection molded product is formed by attaching the transparent polymer sheet 20 and the back sheet 30 on both side surfaces of the solar cell 10 by the adhesive sheet 15, and the polymer resin (polycarbonate injection molding) P is cured on the upper side surface of the transparent polymer sheet 20 and the entire side surface of the preform solar cell 50.

At the present time, the cured polymer resin P is formed on the upper portion of the preform solar cell 50 to a thickness of about 2.5 mm or more and about 5 mm or less, and the preform solar cell 50 may have a thickness of about 2.1 mm or more and about 2.5 mm or less.

On the other hand, the shape of the cured polymer resin P may be determined by the internal shape of the injection mold 60. That is, by varying the shape of the space formed by the gap between the fixed mold 65 and the moving mold 68, the shape of the cured polymer resin P may be varied.

In the present way, according to an exemplary embodiment of the present disclosure, by manufacturing a solar cell module by applying an injection mold used in a plastic molding process, it is possible to produce a solar cell module product with a variety of elegant designs, departing from the conventional simple panel structure made of tempered glass and an aluminum frame.

Additionally, by eliminating the tempered glass and aluminum frame and applying polymer resin, it is possible to reduce the weight dramatically and produce a transparent product.

Furthermore, since it is possible to produce packaged solar cell modules in a single plastic injection molding process using an injection mold, production efficiency may be maximized.

Furthermore, by applying the injection compression molding process, which simultaneously applies injection molding and mold compression, to the manufacturing of solar cell modules, the solar cells inside the mold are not damaged, reducing product defects and enabling the production of reliable products.

While the exemplary embodiments of the present disclosure have been described in detail, it is to be understood that the present disclosure is not limited to the disclosed exemplary embodiments of the present disclosure, but on the other hand, is directed to cover various modifications and equivalent claims as well as various alternatives and modifications thereof. It is intended that the scope of the present disclosure be defined by the Claims appended hereto and their equivalents.”

### DESCRIPTION OF SYMBOLS

10: Solar cell
15: Adhesive sheet
20: Polymer sheet
30: Back sheet
50: Preform solar cell
60: Injection mold
61: Injection molding nozzle
62: Runner
63: Sprue
64: Gate
65: Fixed mold
68: Moving mold
P: Polymer resin

What is claimed is:

1. A method for manufacturing a solar cell module, the method comprising:
manufacturing a preform solar cell by connecting a plurality of solar cells;
inserting and mounting the preform solar cell into an injection mold;
closing the injection mold and injecting and filling a polymer resin into the injection mold to cover the preform solar cell;
operating the injection mold to apply a compressive force to the polymer resin filled in the injection mold;
curing the polymer resin; and
opening the injection mold to extract a solar cell injection molded product.

2. The method for manufacturing the solar cell module of claim 1, wherein in the manufacturing of the preform solar cell, the preform solar cell is formed by:
preparing a plurality of solar cells connected to a conductive string between electrodes,
adhering a transparent polymer sheet to a front surface of the plurality of solar cells by an adhesive sheet, and adhering a back sheet to a back surface of the plurality of solar cells.

3. The method for manufacturing the solar cell module of claim 2, wherein the transparent polymer sheet is a made of polycarbonate (PC).

4. The method for manufacturing the solar cell module of claim 2, wherein the adhesive sheet is made of any one of ethylene vinyl acetate (EVA), polyolefin elastomer (POE), and an acrylic transparent sheet.

5. The method for manufacturing the solar cell module of claim 2, wherein the adhesive sheet is formed to have a thickness of 0.5 mm or more and 0.7 mm or less.

6. The method for manufacturing the solar cell module of claim 1, wherein in the inserting and mounting of the preform solar cell into the injection mold, the injection mold comprises a fixed mold on which the preform solar cell is disposed and a moving mold that moves relative to the fixed mold.

7. The method for manufacturing the solar cell module of claim 6, wherein the fixed mold includes a runner formed therein side, which is a path through which the polymer resin passes, and a sprue formed on an outer portion of the fixed mold, wherein the spruce is connected to a first end portion of the runner and is an inlet through which the polymer resin flows in from an external injection molding nozzle.

8. The method for manufacturing the solar cell module of claim 7, wherein the polymer resin is supplied into the runner through the sprue, and the polymer resin is discharged through a gate formed on an inside of the fixed mold and connected to a second end portion of the runner to cover the preform solar cell disposed on the fixed mold.

9. The method for manufacturing the solar cell module of claim 8, wherein the gate is disposed on first and second sides of a space where the preform solar cell is disposed in the fixed mold, and is formed at a position spaced apart from an edge portion of the fixed mold toward the center of the fixed mold.

10. The method for manufacturing the solar cell module of claim 9, wherein a step is formed between the preform solar cell and the fixed mold, and the polymer resin is filled in an upper space of the preform solar cell formed in the step in the fixed mold.

11. The method for manufacturing the solar cell module of claim 10, wherein the polymer resin covers the upper surface of the preform solar cell and is then induced to fill the edge portion where the step is formed.

12. The method for manufacturing the solar cell module of claim 1, wherein in the injecting and filling of the polymer resin into the injection mold, the fixed mold and the moving mold are closed to form a gap between the fixed mold and the moving mold.

13. The method for manufacturing the solar cell module of claim 11, wherein the gap is formed to be 2 to 2.5 times greater than a thickness of the preform solar cell.

14. The method for manufacturing the solar cell module of claim 13, wherein the polymer resin is filled only in some space within the gap.

15. The method for manufacturing the solar cell module of claim 1, wherein the applying of the compressive force to the polymer resin filled in the injection mold is performed before the polymer resin is completely cured within the injection mold.

16. The method for manufacturing the solar cell module of claim 1, wherein in the curing of the polymer resin, the cured polymer resin is formed on an upper portion of the preform solar cell to a thickness of 2.5 mm or more and 5 mm or less, and the preform solar cell is formed to have a thickness of 2.1 mm or more and 2.5 mm or less.
